(19) United States
(12) Patent Application Publication
(10) Pub. No.: US 2003/0089921 A1
(43) Pub. Date: May 15, 2003

(54) Structure and method for fabricating semiconductor structures and devices utilizing the formation of a compliant substrate having a niobium concentration

(75) Inventors: Dirk C. Jordan, Gilbert, AZ (US); Daniel S. Marshall, Chandler, AZ (US)

Correspondence Address: OBLON, SPIVAK, MCCLELLAND, MAIER & NEUSTADT, P.C., 1940 DUKE STREET, ALEXANDRIA, VA, 22314, US

(73) Assignee: MOTOROLA, INC, Schaumburg, IL

(21) Appl. No.: 09/986,899

(22) Filed: Nov. 13, 2001

(51) Int. Cl. H01L 31/0328

(52) U.S. Cl. 257/200

(57) ABSTRACT

High quality epitaxial layers of monocrystalline materials can be grown overlying monocrystalline substrates such as large silicon wafers by forming a compliant substrate for growing the monocrystalline layers. The compliant substrate includes an accommodating buffer layer comprising a layer of monocrystalline oxide having a niobium concentration that provides for substantial lattice matching of the accommodating buffer layer to the overlying monocrystalline material layer. The monocrystalline oxide of the accommodating buffer layer is selected to be lattice matched to the underlying monocrystalline substrate. The accommodating buffer layer may be spaced apart from the underlying monocrystalline substrate by an amorphous interface layer. The amorphous interface layer dissipates strain and permits the growth of a high quality monocrystalline accommodating buffer layer.

### FIELD OF THE INVENTION

This invention relates generally to semiconductor structures and devices and to a method for their fabrication, and more specifically to semiconductor structures and devices and to the fabrication and use of semiconductor structures, devices, and integrated circuits that utilize a compliant substrate having a niobium concentration to form a monocrystalline material layer comprised of semiconductor material, compound semiconductor material, and/or other types of material such as metals and non-metals.

### BACKGROUND OF THE INVENTION

Semiconductor devices often include multiple layers of conductive, insulating, and semiconductive layers. Often, the desirable properties of such layers improve with the crystallinity of the layer. For example, the electron mobility and band gap of semiconductive layers improves as the crystallinity of the layer increases. Similarly, the free electron concentration of conductive layers and the electron charge displacement and electron energy recoverability of insulative or dielectric films improves as the crystallinity of these layers increases.

For many years, attempts have been made to grow various monolithic thin films on a foreign substrate such as silicon (Si). To achieve optimal characteristics of the various monolithic layers, however, a monocrystalline film of high crystalline quality is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of monocrystalline material to be of low crystalline quality.

If a large area thin film of high quality monocrystalline material was available at low cost, a variety of semiconductor devices could advantageously be fabricated in or using that film at a low cost compared to the cost of fabricating such devices beginning with a bulk wafer of semiconductor material or in an epitaxial film of such material on a bulk wafer of semiconductor material. In addition, if a thin film of high quality monocrystalline material could be realized beginning with a bulk wafer such as a silicon wafer, an integrated device structure could be achieved that took advantage of the best properties of both the silicon and the high quality monocrystalline material.

Accordingly, a need exists for a semiconductor structure that provides a high quality monocrystalline film or layer over another monocrystalline material and for a process for making such a structure. In other words, there is a need for providing the formation of a monocrystalline substrate that is compliant with a high quality monocrystalline material layer so that true two-dimensional growth can be achieved for the formation of quality semiconductor structures, devices and integrated circuits having grown monocrystalline film having the same crystal orientation as an underlying substrate. This monocrystalline material layer may be comprised of a semiconductor material, a compound semiconductor material, and other types of material such as metals and non-metals.

### BRIEF DESCRIPTION OF THE DRAWINGS

The present invention is illustrated by way of example and not limitation in the accompanying figures, in which like references indicate similar elements, and in which:

FIGS. 1, 2, and 3 illustrate schematically, in cross section, device structures in accordance with various embodiments of the invention;

FIG. 4 illustrates graphically the relationship between maximum attainable film thickness and lattice mismatch between a host crystal and a grown crystalline overlayer;

FIG. 5 illustrates a high resolution Transmission Electron Micrograph of a structure including a monocrystalline accommodating buffer layer;

FIG. 6 illustrates an x-ray diffraction spectrum of a structure including a monocrystalline accommodating buffer layer;

FIG. 7 illustrates a high resolution Transmission Electron Micrograph of a structure including an amorphous oxide layer;

FIG. 8 illustrates an x-ray diffraction spectrum of a structure including an amorphous oxide layer;

FIGS. 9-12 illustrate schematically, in cross-section, the formation of a device structure in accordance with another embodiment of the invention;

FIGS. 13-16 illustrate a probable molecular bonding structure of the device structures illustrated in FIGS. 9-12;

FIGS. 17-20 illustrate schematically, in cross-section, the formation of a device structure in accordance with still another embodiment of the invention;

FIGS. 21-23 illustrate schematically, in cross-section, the formation of yet another embodiment of a device structure in accordance with the invention;

FIGS. 24-25 illustrate schematically, in cross-section, device structures in accordance with other various embodiments of the invention; and

FIG. 26 illustrates schematically, in cross-section, a device structure that can be used in accordance with various embodiments of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE DRAWINGS

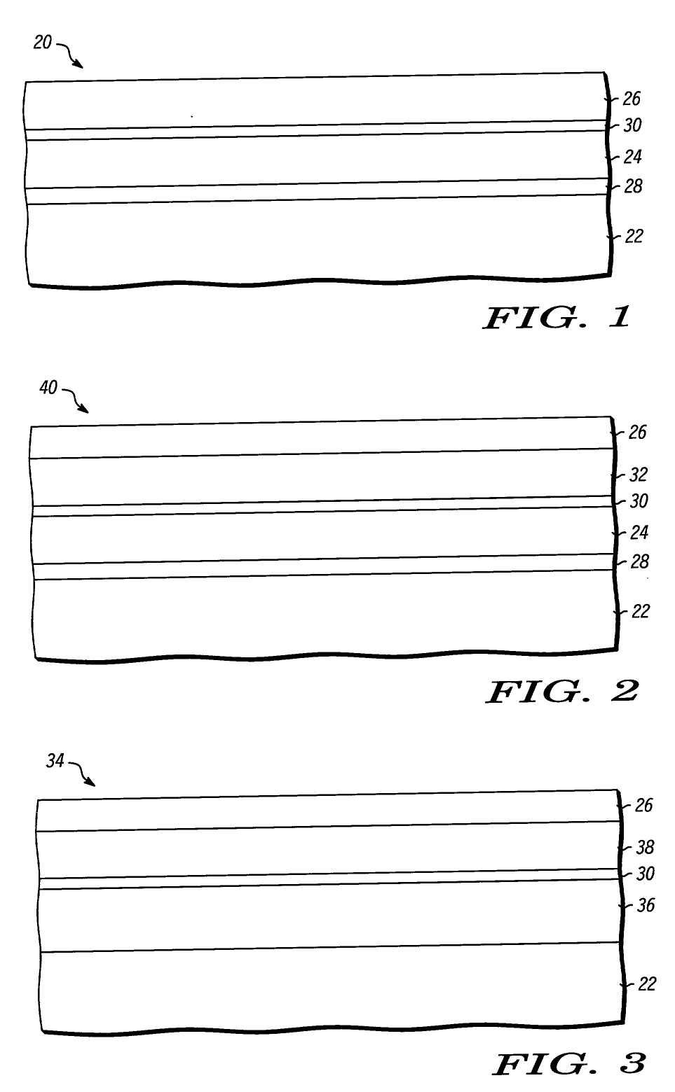

FIG. 1 illustrates schematically, in cross section, a portion of a semiconductor structure 20 in accordance with an embodiment of the invention. Semiconductor structure 20 includes a monocrystalline substrate 22, accommodating buffer layer 24 comprising a monocrystalline material, and a monocrystalline material layer 26. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment of the invention, structure 20 also includes an amorphous interface layer 28 positioned between substrate 22 and accommodating buffer layer 24. Structure 20 may also include a template layer 30 between the accommodating buffer layer and monocrystalline material layer 26. As will be explained more fully below, the template layer helps to initiate the growth of the monocrystalline material layer on the accommodating buffer layer. The amorphous interface layer helps to relieve the strain in the accommodating buffer layer and by doing so, aids in the growth of a high crystalline quality accommodating buffer layer.

Substrate 22, in accordance with an embodiment of the invention, is a monocrystalline semiconductor or compound semiconductor wafer, preferably of large diameter. The wafer can be of, for example, a material from Group IV of the periodic table. Examples of Group IV semiconductor materials include silicon, germanium, mixed silicon and germanium, mixed silicon and carbon, mixed silicon, germanium and carbon, and the like. Preferably substrate 22 is a wafer containing silicon or germanium, and most preferably is a high quality monocrystalline silicon wafer as used in the semiconductor industry. Accommodating buffer layer 24 is preferably a monocrystalline oxide or nitride material epitaxially grown on the underlying substrate. In accordance with one embodiment of the invention, amorphous interface layer 28 is grown on substrate 22 at the interface between substrate 22 and the growing accommodating buffer layer by the oxidation of substrate 22 during the growth of layer 24. The amorphous interface layer serves to relieve strain that might otherwise occur in the monocrystalline accommodating buffer layer as a result of differences in the lattice constants of the substrate and the buffer layer. As used herein, lattice constant refers to the distance between atoms of a cell measured in the plane of the surface. If such strain is not relieved by the amorphous interface layer, the strain may cause defects in the crystalline structure of the accommodating buffer layer. Defects in the crystalline structure of the accommodating buffer layer, in turn, would make it difficult to achieve a high quality crystalline structure in monocrystalline material layer 26 which may comprise a semiconductor material, a compound semiconductor material, or another type of material such as a metal or a non-metal.

Accommodating buffer layer 24 is preferably a monocrystalline oxide or nitride material selected for its crystalline compatibility with the underlying substrate and with the overlying material layer. For example, the material could be an oxide or nitride having a lattice structure closely matched to the substrate and to the subsequently applied monocrystalline material layer. Materials that are suitable for the accommodating buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, alkaline earth metal tin-based perovskites, lanthanum aluminate, lanthanum scandium oxide, gadolinium oxide, and other perovskite oxide materials. Additionally, various nitrides such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxide or nitrides typically include at least two different metallic elements. In some specific applications, the metal oxides or nitrides may include three or more different metallic elements.

Amorphous interface layer 28 is preferably an oxide formed by the oxidation of the surface of substrate 22, and more preferably is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5-5 nm.

The material for monocrystalline material layer 26 can be selected, as desired, for a particular structure or application. For example, the monocrystalline material of layer 26 may comprise a compound semiconductor which can be selected, as needed for a particular semiconductor structure, from any of the Group IIIA and VA elements (III-V semiconductor compounds), mixed III-V compounds, Group II(A or B) and VIA elements (II-VI semiconductor compounds), mixed II-VI compounds, Group IV and VI elements (IV-VI semiconductor compounds), mixed IV-VI compounds, Group IV elements (Group IV semiconductors), and mixed Group IV compounds. Examples include gallium arsenide (GaAs), gallium indium arsenide (GaInAs), gallium aluminum arsenide (GaAIAs), indium phosphide (InP), cadmium sulfide (CdS), cadmium mercury telluride (CdHgTe), zinc selenide (ZnSe), zinc sulfur selenide (ZnSSe), lead selenide (PbSe), lead telluride (PbTe), lead sulfide selenide (PbSSe), silicon (Si), germanium (Ge), silicon germanium (SiGe), silicon germanium carbide (SiGeC), and the like. However, monocrystalline material layer 26 may also comprise other semiconductor materials, metals, or non-metal materials which are used in the formation of semiconductor structures, devices and/or integrated circuits.

Appropriate materials for template 30 are discussed below. Suitable template materials chemically bond to the surface of the accommodating buffer layer 24 at selected sites and provide sites for the nucleation of the epitaxial growth of monocrystalline material layer 26. When used, template layer 30 has a thickness ranging from about 1 to about 10 monolayers.

FIG. 2 illustrates, in cross section, a portion of a semiconductor structure 40 in accordance with a further embodiment of the invention. Structure 40 is similar to the previously described semiconductor structure 20, except that an additional buffer layer 32 is positioned between accommodating buffer layer 24 and monocrystalline material layer 26. Specifically, the additional buffer layer is positioned between template layer 30 and the overlying layer of monocrystalline material. The additional buffer layer, formed of a semiconductor or compound semiconductor material when the monocrystalline material layer 26 comprises a semiconductor or compound semiconductor material, serves to provide a lattice compensation when the lattice constant of the accommodating buffer layer cannot be adequately matched to the overlying monocrystalline semiconductor or compound semiconductor material layer.

FIG. 3 schematically illustrates, in cross section, a portion of a semiconductor structure 34 in accordance with another exemplary embodiment of the invention. Structure 34 is similar to structure 20, except that structure 34 includes an amorphous layer 36, rather than accommodating buffer layer 24 and amorphous interface layer 28, and an additional monocrystalline layer 38.

As explained in greater detail below, amorphous layer 36 may be formed by first forming an accommodating buffer layer and an amorphous interface layer in a similar manner to that described above. Monocrystalline layer 38 is then formed (by epitaxial growth) overlying the monocrystalline accommodating buffer layer. The accommodating buffer layer may then be optionally exposed to an anneal process to convert at least a portion of the monocrystalline accommodating buffer layer to an amorphous layer. Amorphous layer 36 formed in this manner comprises materials from both the accommodating buffer and interface layers, which amorphous layers may or may not amalgamate. Thus, layer 36 may comprise one or two amorphous layers. Formation of amorphous layer 36 between substrate 22 and additional monocrystalline layer 26 (subsequent to layer 38 formation) relieves stresses between layers 22 and 38 and provides a true compliant substrate for subsequent processing—e.g., monocrystalline material layer 26 formation.

The processes previously described above in connection with FIGS. 1 and 2 are adequate for growing monocrystalline material layers over a monocrystalline substrate. However, the process described in connection with FIG. 3, which includes transforming at least a portion of a monocrystalline accommodating buffer layer to an amorphous oxide layer, may be better for growing monocrystalline material layers because it allows any strain in layer 26 to relax.

Additional monocrystalline layer 38 may include any of the materials described throughout this application in connection with either of monocrystalline material layer 26 or additional buffer layer 32. For example, when monocrystalline material layer 26 comprises a semiconductor or compound semiconductor material, layer 38 may include monocrystalline Group IV or monocrystalline compound semiconductor materials.

In accordance with one embodiment of the present invention, additional monocrystalline layer 38 serves as an anneal cap during layer 36 formation and as a template for subsequent monocrystalline layer 26 formation. Accordingly, layer 38 is preferably thick enough to provide a suitable template for layer 26 growth (at least one monolayer) and thin enough to allow layer 38 to form as a substantially defect free monocrystalline material.

In accordance with another embodiment of the invention, additional monocrystalline layer 38 comprises monocrystalline material (e.g., a material discussed above in connection with monocrystalline layer 26) that is thick enough to form devices within layer 38. In this case, a semiconductor structure in accordance with the present invention does not include monocrystalline material layer 26. In other words, the semiconductor structure in accordance with this embodiment only includes one monocrystalline layer disposed above amorphous oxide layer 36.

The following non-limiting, illustrative examples illustrate various combinations of materials useful in structures 20, 40, and 34 in accordance with various alternative embodiments of the invention. These examples are merely illustrative, and it is not intended that the invention be limited to these illustrative examples.

### EXAMPLE 1

In accordance with one embodiment of the invention, monocrystalline substrate 22 is a silicon substrate oriented in the (100) direction. The silicon substrate can be, for example, a silicon substrate as is commonly used in making complementary metal oxide semiconductor (CMOS) integrated circuits having a diameter of about 200-300 mm. In accordance with this embodiment of the invention, accommodating buffer layer 24 is a monocrystalline layer of Sr_{z}Ba_{1-z}TiO₃ where z ranges from 0 to 1 and the amorphous interface layer is a layer of silicon oxide (SiOₓ) formed at the interface between the silicon substrate and the accommodating buffer layer. The value of z is selected to obtain one or more lattice constants closely matched to corresponding lattice constants of the subsequently formed layer 26. The accommodating buffer layer can have a thickness of about 2 to about 100 nanometers (nm) and preferably has a thickness of about 5 nm. In general, it is desired to have an accommodating buffer layer thick enough to isolate the monocrystalline material layer 26 from the substrate to obtain the desired electrical and optical properties. Layers thicker than 100 nm usually provide little additional benefit while increasing cost unnecessarily; however, thicker layers may be fabricated if needed. The amorphous interface layer of silicon oxide can have a thickness of about 0.5-5 nm, and preferably a thickness of about 1 to 2 nm.

In accordance with this embodiment of the invention, monocrystalline material layer 26 is a compound semiconductor layer of gallium arsenide (GaAs) or aluminum gallium arsenide (AlGaAs) having a thickness of about 1 nm to about 100 micrometers (μm) and preferably a thickness of about 0.5 μm to 10 μm. The thickness generally depends on the application for which the layer is being prepared. To facilitate the epitaxial growth of the gallium arsenide or aluminum gallium arsenide on the monocrystalline oxide, a template layer is formed by capping the oxide layer. The template layer is preferably 0.5-10 monolayers of Ti—As, Ti—O—As, Ti—O—Ga, Sr—O—As, Sr—Ga—O, or Sr—Al—O. By way of a preferred example, 0.5-2 monolayers of Ti—As or TiO—O—As have been illustrated to successfully grow GaAs layers.

### EXAMPLE 2

In accordance with a further embodiment of the invention, monocrystalline substrate 22 is a silicon substrate as described above. The accommodating buffer layer is a monocrystalline oxide of strontium or barium zirconate or hafnate in a cubic or orthorhombic phase with an amorphous interface layer of silicon oxide formed at the interface between the silicon substrate and the accommodating buffer layer. The accommodating buffer layer can have a thickness of about 2-100 nm and preferably has a thickness of at least 4 nm to ensure adequate crystalline and surface quality and is formed of a monocrystalline SrZrO₃, BaZrO₃, SrHfO₃, BaSnO₃ or BaHfO₃. For example, a monocrystalline oxide layer of BaZrO₃ can grow at a temperature of about 700 degrees C. The lattice structure of the resulting crystalline oxide exhibits a 45 degree rotation with respect to the substrate silicon lattice structure.

An accommodating buffer layer formed of these zirconate or hafnate materials is suitable for the growth of a monocrystalline material layer which comprises compound semiconductor materials in the indium phosphide (InP) system. In this system, the compound semiconductor material can be, for example, indium phosphide (InP), indium gallium arsenide (InGaAs), aluminum indium arsenide, (AlInAs), or aluminum gallium indium arsenic phosphide (AlGaInAsP), having a thickness of about 1.0 nm to 10 μm. A suitable template for this structure is about 0.5-1 monolayer of one of a material M-N and a material M—O—N, wherein M is selected from at least one of Zr, Hf, Ti, Sr, and Ba and N is selected from at least one of As, P, Ga, Al and In. Alternatively, the template may comprise 0.5-10 monolayers of zirconium-arsenic (Zr—As), zirconium-phosphorus (Zr—P), hafnium-arsenic (Hf—As), hafnium-phosphorus (Hf—P), strontium-oxygen-arsenic (Sr—O—As), strontium-oxygen-phosphorus (Sr—O—P), barium-oxygen-arsenic (Ba—O—As), indium-strontium-oxygen (In—Sr—O), or barium-oxygen-phosphorus (Ba—O—P), and preferably 1-2 monolayers of one of these materials. By way of an example, for a barium zirconate accommodating buffer layer, the surface is terminated with 0.5-2 monolayers of zirconium followed by deposition of 0.5-2 monolayers of arsenic to form a Zr—As template. A monocrystalline layer of the compound semiconductor material from the indium phosphide system is then grown on the template layer. The resulting lattice structure of the compound semiconductor material exhibits a 45 degree rotation with respect to the accommodating buffer layer lattice structure and a lattice mismatch to (100) InP of less than 2.5%, and preferably less than about 1.0%.

### EXAMPLE 3

In accordance with a further embodiment of the invention, a structure is provided that is suitable for the growth of an epitaxial film of a monocrystalline material comprising a II-VI material overlying a silicon substrate. The substrate is preferably a silicon wafer as described above. A suitable accommodating buffer layer material is SrₓBa₁₋ₓTiO₃, where x ranges from 0 to 1, having a thickness of about 2-100 nm and preferably a thickness of about 3-10 nm. Where the monocrystalline layer comprises a compound semiconductor material, the II-VI compound semiconductor material can be, for example, zinc selenide (ZnSe) or zinc sulfur selenide (ZnSSe). A suitable template for this material system includes 0.5-10 monolayers of zinc-oxygen (Zn—O) followed by 0.5-2 monolayers of an excess of zinc followed by the selenidation of zinc on the surface. Alternatively, a template can be, for example, 0.5-10 monolayers of strontium-sulfur (Sr—S) followed by the ZnSeS.

### EXAMPLE 4

This embodiment of the invention is an example of structure 40 illustrated in FIG. 2. Substrate 22, accommodating buffer layer 24, and monocrystalline material layer 26 can be similar to those described in example 1. In addition, an additional buffer layer 32 serves to alleviate any strains that might result from a mismatch of the crystal lattice of the accommodating buffer layer and the lattice of the monocrystalline material. Buffer layer 32 can be a layer of germanium or a GaAs, an aluminum gallium arsenide (AlGaAs), an indium gallium phosphide (InGaP), an aluminum gallium phosphide (AlGaP), an indium gallium arsenide (InGaAs), an aluminum indium phosphide (AlInP), a gallium arsenide phosphide (GaAsP), or an indium gallium phosphide (InGaP) strain compensated superlattice. In accordance with one aspect of this embodiment, buffer layer 32 includes a GaAsₓP₁₋ₓ superlattice, wherein the value of x ranges from 0 to 1. In accordance with another aspect, buffer layer 32 includes an In_{y}Ga_{1-y}P superlattice, wherein the value of y ranges from 0 to 1. By varying the value of x or y, as the case may be, the lattice constant is varied from bottom to top across the superlattice to create a match between lattice constants of the underlying oxide and the overlying monocrystalline material which in this example is a compound semiconductor material. The compositions of other compound semiconductor materials, such as those listed above, may also be similarly varied to manipulate the lattice constant of layer 32 in a like manner. The superlattice can have a thickness of about 50-500 nm and preferably has a thickness of about 100-200 nm. The superlattice period can have a thickness of about 2-15 nm, preferably 2-10 nm. The template for this structure can be the same of that described in example 1. Alternatively, buffer layer 32 can be a layer of monocrystalline germanium having a thickness of 1-50 nm and preferably having a thickness of about 2-20 nm. In using a germanium buffer layer, a template layer of either germanium-strontium (Ge—Sr) or germanium-titanium (Ge—Ti) having a thickness of about 0.5-2 monolayers can be used as a nucleating site for the subsequent growth of the monocrystalline material layer which in this example is a compound semiconductor material. The formation of the oxide layer is capped with either a 0.5-1 monolayer of strontium or a 0.5-1 monolayer of titanium to act as a nucleating site for the subsequent deposition of the monocrystalline germanium. The layer of strontium or titanium provides a nucleating site to which the first monolayer of germanium can bond.

### EXAMPLE 5

This example also illustrates materials useful in a structure 40 as illustrated in FIG. 2. Substrate material 22, accommodating buffer layer 24, monocrystalline material layer 26 and template layer 30 can be the same as those described above in example 2. In addition, additional buffer layer 32 is inserted between the accommodating buffer layer and the overlying monocrystalline material layer. The buffer layer, a further monocrystalline material which in this instance comprises a semiconductor material, can be, for example, a graded layer of indium gallium arsenide (InGaAs) or indium aluminum arsenide (InAlAs). In accordance with one aspect of this embodiment, additional buffer layer 32 includes InGaAs, in which the indium composition varies from 0 to about 50%. The additional buffer layer 32 preferably has a thickness of about 10-30 nm. Varying the composition of the buffer layer from GaAs to InGaAs serves to provide a lattice match between the underlying monocrystalline oxide material and the overlying layer of monocrystalline material which in this example is a compound semiconductor material. Such a buffer layer is especially advantageous if there is a lattice mismatch between accommodating buffer layer 24 and monocrystalline material layer 26.

### EXAMPLE 6

This example provides exemplary materials useful in structure 34, as illustrated in FIG. 3. Substrate material 22, template layer 30, and monocrystalline material layer 26 may be the same as those described above in connection with example 1.

Amorphous layer 36 is an amorphous oxide layer which is suitably formed of a combination of amorphous interface layer materials (e.g., layer 28 materials as described above) and accommodating buffer layer materials (e.g., layer 24 materials as described above). For example, amorphous layer 36 may include a combination of SiOₓ and Sr_{z}Ba_{1-z} TiO₃ (where z ranges from 0 to 1), which combine or mix, at least partially, during an anneal process to form amorphous oxide layer 36.

The thickness of amorphous layer 36 may vary from application to application and may depend on such factors as desired insulating properties of layer 36, type of monocrystalline material comprising layer 26, and the like. In accordance with one exemplary aspect of the present embodiment, layer 36 thickness is about 1 nm to about 100 nm, preferably about 1-10 nm, and more preferably about 3-5 nm.

Layer 38 comprises a monocrystalline material that can be grown epitaxially over a monocrystalline oxide material such as material used to form accommodating buffer layer 24. In accordance with one embodiment of the invention, layer 38 includes the same materials as those comprising layer 26. For example, if layer 26 includes GaAs, layer 38 also includes GaAs. However, in accordance with other embodiments of the present invention, layer 38 may include materials different from those used to form layer 26. In accordance with one exemplary embodiment of the invention, layer 38 is about 1 nm to about 500 nm thick.

Referring again to FIGS. 1-3, substrate 22 is a monocrystalline substrate such as a monocrystalline silicon or gallium arsenide substrate. The crystalline structure of the monocrystalline substrate is characterized by a lattice constant and by a lattice orientation. In similar manner, accommodating buffer layer 24 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

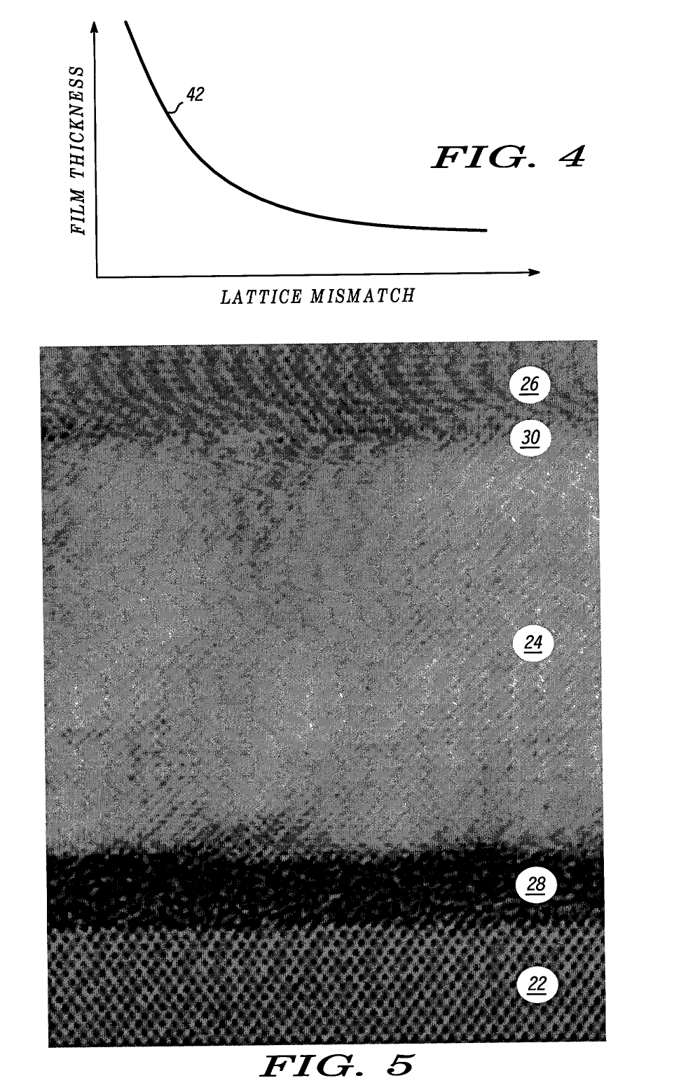

FIG. 4 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, substrate 22 is a (100) oriented monocrystalline silicon wafer and accommodating buffer layer 24 is a layer of strontium barium titanate. Substantial matching of lattice constants between these two materials is achieved by rotating the crystal orientation of the titanate material by 45° with respect to the crystal orientation of the silicon substrate wafer. The inclusion in the structure of amorphous interface layer 28, a silicon oxide layer in this example, if it is of sufficient thickness, serves to reduce strain in the titanate monocrystalline layer that might result from any mismatch in the lattice constants of the host silicon wafer and the grown titanate layer. As a result, in accordance with an embodiment of the invention, a high quality, thick, monocrystalline titanate layer is achievable.

Still referring to FIGS. 1-3, layer 26 is a layer of epitaxially grown monocrystalline material and that crystalline material is also characterized by a crystal lattice constant and a crystal orientation. In accordance with one embodiment of the invention, the lattice constant of layer 26 differs from the lattice constant of substrate 22. To achieve high crystalline quality in this epitaxially grown monocrystalline layer, the accommodating buffer layer must be of high crystalline quality. In addition, in order to achieve high crystalline quality in layer 26, substantial matching between the crystal lattice constant of the host crystal, in this case, the monocrystalline accommodating buffer layer, and the grown crystal is desired. With properly selected materials this substantial matching of lattice constants is achieved as a result of rotation of the crystal orientation of the grown crystal with respect to the orientation of the host crystal. For example, if the grown crystal is gallium arsenide, aluminum gallium arsenide, zinc selenide, or zinc sulfur selenide and the accommodating buffer layer is monocrystalline SrₓBa₁₋ₓTiO₃, substantial matching of crystal lattice constants of the two materials is achieved, wherein the crystal orientation of the grown layer is rotated by 45° with respect to the orientation of the host monocrystalline oxide. Similarly, if the host material is a strontium or barium zirconate or a strontium or barium hafnate or barium tin oxide and the compound semiconductor layer is indium phosphide or gallium indium arsenide or aluminum indium arsenide, substantial matching of crystal lattice constants can be achieved by rotating the orientation of the grown crystal layer by 45° with respect to the host oxide crystal. In some instances, a crystalline semiconductor buffer layer between the host oxide and the grown monocrystalline material layer can be used to reduce strain in the grown monocrystalline material layer that might result from small differences in lattice constants. Better crystalline quality in the grown monocrystalline material layer can thereby be achieved.

The following example illustrates a process, in accordance with one embodiment of the invention, for fabricating a semiconductor structure such as the structures depicted in FIGS. 1-3. The process starts by providing a monocrystalline semiconductor substrate comprising silicon or germanium. In accordance with a preferred embodiment of the invention, the semiconductor substrate is a silicon wafer having a (100) orientation. The substrate is oriented on axis or, at most, about 6° off axis. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer (preferably 1-3 monolayers) of strontium, barium, a combination of strontium and barium, or other alkaline earth metals or combinations of alkaline earth metals in an MBE apparatus. In the case where strontium is used, the substrate is then heated to a temperature above 720° C. or higher to cause the strontium to react with the native silicon oxide layer. The strontium serves to reduce the silicon oxide to leave a silicon oxide-free surface. The resultant surface may exhibit an ordered 2×1 structure. If an ordered (2×1) structure has not been achieved at this stage of the process, the structure may be exposed to additional strontium until an ordered (2×1) structure is obtained. The ordered 2×1 structure forms a template for the ordered growth of an overlying layer of a monocrystalline oxide. The template provides the necessary chemical and physical properties to nucleate the crystalline growth of an overlying layer.

In accordance with an alternate embodiment of the invention, the native silicon oxide can be converted and the substrate surface can be prepared for the growth of a monocrystalline oxide layer by depositing an alkaline earth metal oxide, such as strontium oxide, strontium barium oxide, or barium oxide, onto the substrate surface by MBE at a low temperature and by subsequently heating the structure to a temperature of above 720° C. At this temperature a solid state reaction takes place between the strontium oxide and the native silicon oxide causing the reduction of the native silicon oxide and leaving an ordered 2×1 structure on the substrate surface. If an ordered (2×1) structure has not been achieved at this stage of the process, the structure may be exposed to additional strontium until an ordered (2×1) structure is obtained. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-800° C., preferably 350-450° C., and a layer of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stoichiometric strontium titanate at a growth rate of about 0.1-0.8 nm per minute, preferably 0.3-0.5 nm per minute. After initiating growth of the strontium titanate, the partial pressure of oxygen is increased above the initial minimum value. The stoichiometry of the titanium can be controlled during growth by monitoring RHEED patterns and adjusting the titanium flux. The overpressure of oxygen causes the growth of an amorphous silicon oxide layer at the interface between the underlying substrate and the strontium titanate layer. This step may be applied either during or after the growth of the strontium titanate layer. The growth of the silicon oxide layer results from the diffusion of oxygen through the strontium titanate layer to the interface where the oxygen reacts with silicon at the surface of the underlying substrate. The strontium titanate grows as an ordered (100) monocrystal with the (100) crystalline orientation rotated by 45° with respect to the underlying substrate. Strain that otherwise might exist in the strontium titanate layer because of the small mismatch in lattice constant between the silicon substrate and the growing crystal is relieved in the amorphous silicon oxide interface layer.

After the strontium titanate layer has been grown to the desired thickness, the monocrystalline strontium titanate is capped by a template layer that is conducive to the subsequent growth of an epitaxial layer of a desired monocrystalline material. For example, for the subsequent growth of a monocrystalline compound semiconductor material layer of gallium arsenide, the MBE growth of the strontium titanate monocrystalline layer can be capped by terminating the growth with 0.5-2 monolayers of titanium, 0.5-2 monolayers of titanium-oxygen, or with 0.5-2 monolayers of strontium-oxygen. Following the formation of this capping layer, arsenic is deposited to form a Ti—As bond, a Ti—O—As bond or a Sr—O—As bond. Any of these form an appropriate template for deposition and formation of a gallium arsenide monocrystalline layer. Following the formation of the template, gallium is subsequently introduced to the reaction with the arsenic and gallium arsenide forms. Alternatively, gallium can be deposited on the capping layer to form a Sr—O—Ga bond, a Sr—H—Ga bond, a Ti—H—Ga bond or a Ti—O—Ga bond, and arsenic is subsequently introduced with the gallium to form the GaAs.

FIG. 5 is a high resolution Transmission Electron Micrograph (TEM) of semiconductor material manufactured in accordance with one embodiment of the present invention. Single crystal SrTiO₃ accommodating buffer layer 24 was grown epitaxially on silicon substrate 22. During this growth process, amorphous interfacial layer 28 is formed which relieves strain due to lattice mismatch. GaAs compound semiconductor layer 26 was then grown epitaxially using template layer 30.

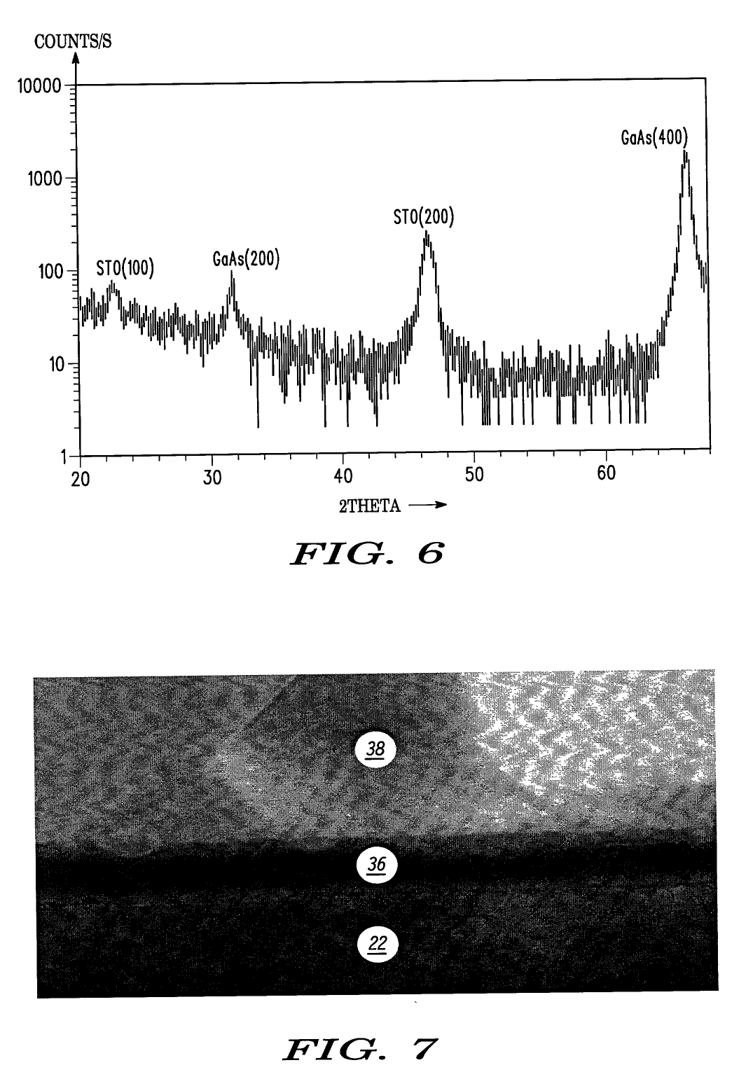

FIG. 6 illustrates an x-ray diffraction spectrum taken on a structure including GaAs monocrystalline layer 26 comprising GaAs grown on silicon substrate 22 using accommodating buffer layer 24. The peaks in the spectrum indicate that both the accommodating buffer layer 24 and GaAs compound semiconductor layer 26 are single crystal and (100) orientated.

The structure illustrated in FIG. 2 can be formed by the process discussed above with the addition of an additional buffer layer deposition step. The additional buffer layer 32 is formed overlying the template layer before the deposition of the monocrystalline material layer. If the buffer layer is a monocrystalline material comprising a compound semiconductor superlattice, such a superlattice can be deposited, by MBE for example, on the template described above. If instead the buffer layer is a monocrystalline material layer comprising a layer of germanium, the process above is modified to cap the strontium titanate monocrystalline layer with a final layer of either strontium or titanium and then by depositing germanium to react with the strontium or titanium. The germanium buffer layer can then be deposited directly on this template.

Structure 34, illustrated in FIG. 3, may be formed by growing an accommodating buffer layer, forming an amorphous oxide layer over substrate 22, and growing semiconductor layer 38 over the accommodating buffer layer, as described above. The accommodating buffer layer and the amorphous oxide layer are then exposed to an anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 36. Layer 26 is then subsequently grown over layer 38. Alternatively, the anneal process may be carried out subsequent to growth of layer 26.

In accordance with one aspect of this embodiment, layer 36 is formed by exposing substrate 22, the accommodating buffer layer, the amorphous oxide layer, and monocrystalline layer 38 to a rapid thermal anneal process with a peak temperature of about 700° C. to about 1000° C. and a process time of about 5 seconds to about 20 minutes. However, other suitable anneal processes may be employed to convert the accommodating buffer layer to an amorphous layer in accordance with the present invention. For example, laser annealing, electron beam annealing, or “conventional” thermal annealing processes (in the proper environment) may be used to form layer 36. When conventional thermal annealing is employed to form layer 36, an overpressure of one or more constituents of layer 30 may be required to prevent degradation of layer 38 during the anneal process. For example, when layer 38 includes GaAs, the anneal environment preferably includes an overpressure of arsenic to mitigate degradation of layer 38.

As noted above, layer 38 of structure 34 may include any materials suitable for either of layers 32 or 26. Accordingly, any deposition or growth methods described in connection with either layer 32 or 26, may be employed to deposit layer 38.

FIG. 7 is a high resolution TEM of semiconductor material manufactured in accordance with the embodiment of the invention illustrated in FIG. 3. In accordance with this embodiment, a single crystal SrTiO₃ accommodating buffer layer was grown epitaxially on silicon substrate 22. During this growth process, an amorphous interfacial layer forms as described above. Next, additional monocrystalline layer 38 comprising a compound semiconductor layer of GaAs is formed above the accommodating buffer layer and the accommodating buffer layer is exposed to an anneal process to form amorphous oxide layer 36.

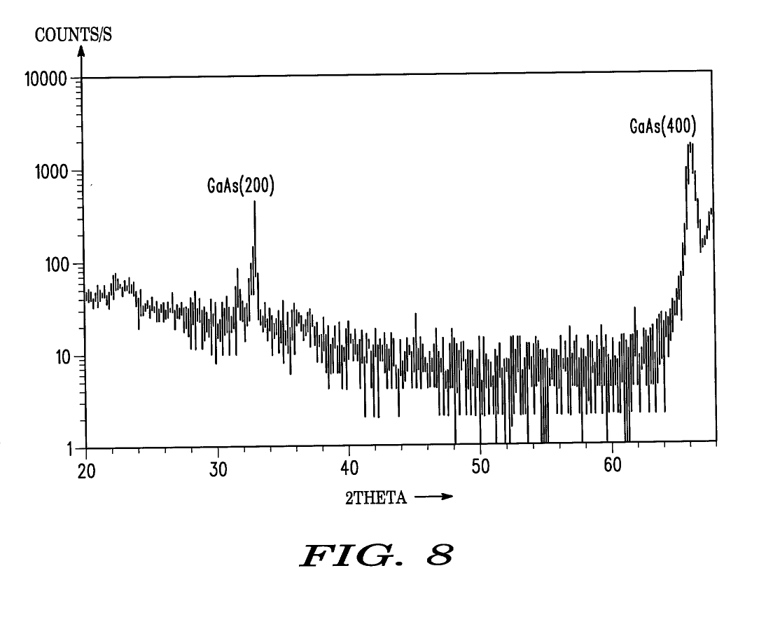

FIG. 8 illustrates an x-ray diffraction spectrum taken on a structure including additional monocrystalline layer 38 comprising a GaAs compound semiconductor layer and amorphous oxide layer 36 formed on silicon substrate 22. The peaks in the 6spectrum indicate that GaAs compound semiconductor layer 38 is single crystal and (100) orientated and the lack of peaks around 40 to 50 degrees indicates that layer 36 is amorphous.

The process described above illustrates a process for forming a semiconductor structure including a silicon substrate, an overlying oxide layer, and a monocrystalline material layer comprising a gallium arsenide compound semiconductor layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers such as alkaline earth metal titanates, zirconates, hafnates, tantalates, vanadates, ruthenates, and niobates, alkaline earth metal tin-based perovskites, lanthanum aluminate, lanthanum scandium oxide, and gadolinium oxide can also be grown. Further, by a similar process such as MBE, other monocrystalline material layers comprising other III-VI and IV-VI monocrystalline compound semiconductors, semiconductors, metals and non-metals can be deposited overlying the monocrystalline oxide accommodating buffer layer.

Each of the variations of monocrystalline material layer and monocrystalline oxide accommodating buffer layer uses an appropriate template for initiating the growth of the monocrystalline material layer. For example, if the accommodating buffer layer is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide respectively. Similarly, if the monocrystalline oxide accommodating buffer layer is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium titanate can be capped with a layer of strontium or strontium and oxygen and barium titanate can be capped with a layer of barium or barium and oxygen. Each of these depositions can be followed by the deposition of arsenic or phosphorus to react with the capping material to form a template for the deposition of a monocrystalline material layer comprising compound semiconductors such as indium gallium arsenide, indium aluminum arsenide, or indium phosphide.

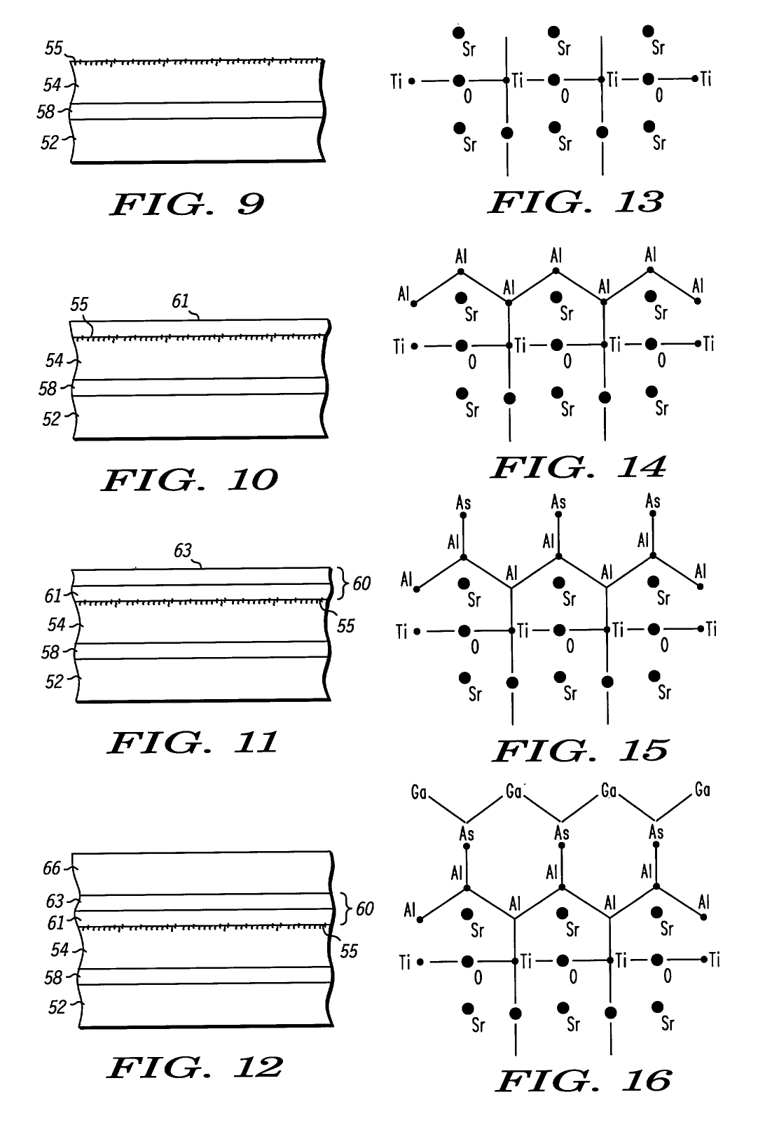

The formation of a device structure in accordance with another embodiment of the invention is illustrated schematically in cross-section in FIGS. 9-12. Like the previously described embodiments referred to in FIGS. 1-3, this embodiment of the invention involves the process of forming a compliant substrate utilizing the epitaxial growth of single crystal oxides, such as the formation of accommodating buffer layer 24 previously described with reference to FIGS. 1 and 2 and amorphous layer 36 previously described with reference to FIG. 3, and the formation of a template layer 30. However, the embodiment illustrated in FIGS. 9-12 utilizes a template that includes a surfactant to facilitate layer-by-layer monocrystalline material growth.

Turning now to FIG. 9, an amorphous interface layer 58 is grown on substrate 52 at the interface between substrate 52 and a growing accommodating buffer layer 54, which is preferably a monocrystalline crystal oxide layer, by the oxidation of substrate 52 during the growth of layer 54. Layer 54 is preferably a monocrystalline oxide material such as a monocrystalline layer of Sr_{z}Ba_{1-z}TiO₃ where z ranges from 0 to 1. However, layer 54 may also comprise any of those compounds previously described with reference layer 24 in FIGS. 1-2 and any of those compounds previously described with reference to layer 36 in FIG. 3 which is formed from layers 24 and 28 referenced in FIGS. 1 and 2.

Layer 54 is grown with a strontium (Sr) terminated surface represented in FIG. 9 by hatched line 55 which is followed by the addition of a template layer 60 which includes a surfactant layer 61 and capping layer 63 as illustrated in FIGS. 10 and 11. Surfactant layer 61 may comprise, but is not limited to, elements such as Al, In and Ga, but will be dependent upon the composition of layer 54 and the overlying layer of monocrystalline material for optimal results. In one exemplary embodiment, aluminum (Al) is used for surfactant layer 61 and functions to modify the surface and surface energy of layer 54. Preferably, surfactant layer 61 is epitaxially grown, to a thickness of 0.5-5.0 monolayers, over layer 54 as illustrated in FIG. 10 by way of molecular beam epitaxy (MBE), although other epitaxial processes may also be performed including chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like.

Surfactant layer 61 is then exposed to a Group V element such as arsenic, for example, to form capping layer 63 as illustrated in FIG. 11. Surfactant layer 61 may be exposed to a number of materials to create capping layer 63 such as elements which include, but are not limited to, As, P, Sb and N. Surfactant layer 61 and capping layer 63 combine to form template layer 60.

Monocrystalline material layer 66, which in this example is a compound semiconductor such as GaAs, is then deposited via MBE, CVD, MOCVD, MEE, ALE, PVD, CSD, PLD, and the like to form the final structure illustrated in FIG. 12.

FIGS. 13-16 illustrate possible molecular bond structures for a specific example of a compound semiconductor structure formed in accordance with the embodiment of the invention illustrated in FIGS. 9-12. More specifically, FIGS. 13-16 illustrate the growth of GaAs (layer 66) on the strontium terminated surface of a strontium titanate monocrystalline oxide (layer 54) using a surfactant containing template (layer 60).

The growth of a monocrystalline material layer 66 such as GaAs on an accommodating buffer layer 54 such as a strontium titanium oxide over amorphous interface layer 58 and substrate layer 52, both of which may comprise materials previously described with reference to layers 28 and 22, respectively in FIGS. 1 and 2, illustrates a critical thickness of about 100 nm where the two-dimensional (2D) and three-dimensional (3D) growth shifts because of the surface energies involved. In order to maintain a true layer by layer growth (Frank-Van der Merwe growth), the following relationship must be satisfied:

δ_{STO}>(δ_{INT}+δ_{GaAs})

where the surface energy of the accommodating buffer layer 54 must be greater than the energy of the interface between the monocrystalline oxide layer 54 and the GaAs layer 66 added to the surface energy of the GaAs layer 66. Since it is impracticable to satisfy this equation, a surfactant containing template was used, as described above with reference to FIGS. 10-12, to increase the surface energy of the monocrystalline oxide layer 54 and also to shift the crystalline structure of the template to a diamond-like structure that is in compliance with the original GaAs layer.

FIG. 13 illustrates the molecular bond structure of a strontium terminated surface of a strontium titanate monocrystalline oxide layer. An aluminum surfactant layer is deposited on top of the strontium terminated surface and bonds with that surface as illustrated in FIG. 14, which reacts to form a capping layer comprising a monolayer of Al₂Sr having the molecular bond structure illustrated in FIG. 14 which forms a diamond-like structure with an sp hybrid terminated surface that is compliant with compound semiconductors such as GaAs. The structure is then exposed to As to form a layer of AlAs as shown in FIG. 15. GaAs is then deposited to complete the molecular bond structure illustrated in FIG. 16 which has been obtained by 2D growth. The GaAs can be grown to any thickness for forming other semiconductor structures, devices, or integrated circuits. Alkaline earth metals such as those in Group IIA are those elements preferably used to form the capping surface of the monocrystalline oxide layer 54 because they are capable of forming a desired molecular structure with aluminum.

In this embodiment, a surfactant containing template layer aids in the formation of a compliant substrate for the monolithic integration of various material layers including those comprised of Group III-V compounds to form high quality semiconductor structures, devices and integrated circuits. For example, a surfactant containing template may be used for the monolithic integration of a monocrystalline material layer such as a layer comprising Germanium (Ge), for example, to form high efficiency photocells.

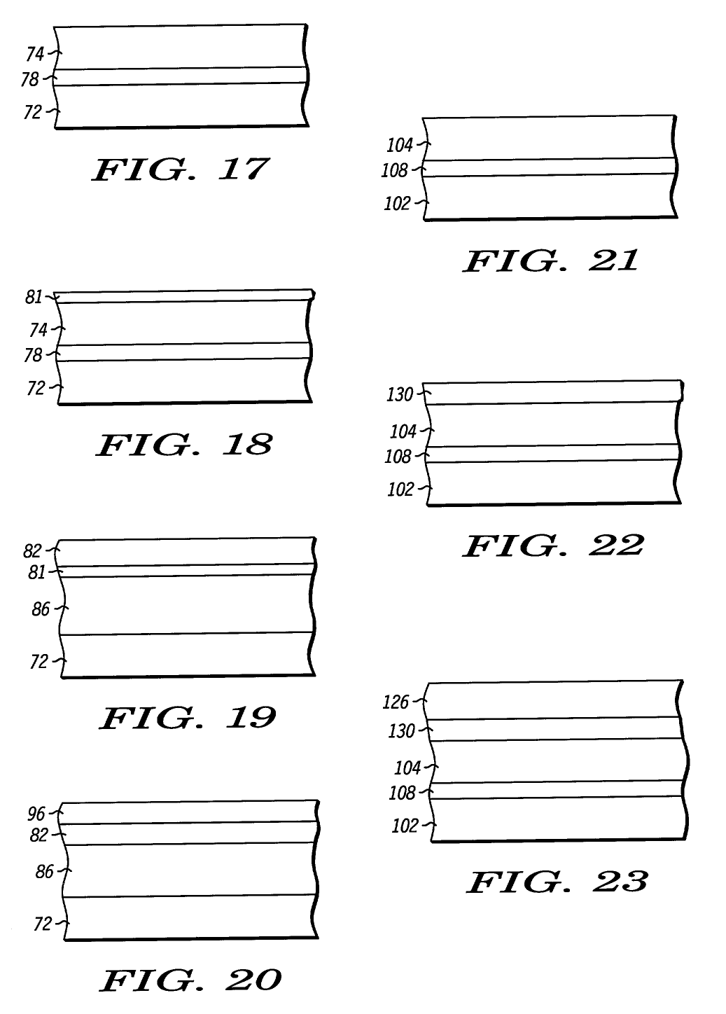

Turning now to FIGS. 17-20, the formation of a device structure in accordance with still another embodiment of the invention is illustrated in cross-section. This embodiment utilizes the formation of a compliant substrate which relies on the epitaxial growth of single crystal oxides on silicon followed by the epitaxial growth of single crystal silicon onto the oxide.

An accommodating buffer layer 74 such as a monocrystalline oxide layer is first grown on a substrate layer 72, such as silicon, with an amorphous interface layer 78 as illustrated in FIG. 17. Monocrystalline oxide layer 74 may be comprised of any of those materials previously discussed with reference to layer 24 in FIGS. 1 and 2, while amorphous interface layer 78 is preferably comprised of any of those materials previously described with reference to the layer 28 illustrated in FIGS. 1 and 2. Substrate 72, although preferably silicon, may also comprise any of those materials previously described with reference to substrate 22 in FIGS. 1-3.

Next, a silicon layer 81 is deposited over monocrystalline oxide layer 74 via MBE, CVD, MOCVD, MEE, ALE, PVD, CSD, PLD, and the like as illustrated in FIG. 18 with a thickness of a few tens of nanometers preferably with a thickness of about 5 nm. Monocrystalline oxide layer 74 preferably has a thickness of about 2 to 10 nm.

Rapid thermal annealing is then conducted in the presence of a carbon source such as acetylene or methane, for example at a temperature within a range of about 800° C. to 1000° C. to form capping layer 82 and silicate amorphous layer 86. However, other suitable carbon sources may be used as long as the rapid thermal annealing step functions to amorphize the monocrystalline oxide layer74 into a silicate amorphous layer 86 and carbonize the top silicon layer 81 to form capping layer 82 which in this example would be a silicon carbide (SiC) layer as illustrated in FIG. 19. The formation of amorphous layer 86 is similar to the formation of layer 36 illustrated in FIG. 3 and may comprise any of those materials described with reference to layer 36 in FIG. 3 but the preferable material will be dependent upon the capping layer 82 used for silicon layer 81.

Finally, a compound semiconductor layer 96, such as gallium nitride (GaN) is grown over the SiC surface by way of MBE, CVD, MOCVD, MEE, ALE, PVD, CSD, PLD, or the like to form a high quality compound semiconductor material for device formation. More specifically, the deposition of GaN and GaN based systems such as GaInN and AlGaN will result in the formation of dislocation nets confined at the silicon/amorphous region. The resulting nitride containing compound semiconductor material may comprise elements from groups III, IV and V of the periodic table and is defect free.

Although GaN has been grown on SiC substrate in the past, this embodiment of the invention possesses a one step formation of the compliant substrate containing a SiC top surface and an amorphous layer on a Si surface. More specifically, this embodiment of the invention uses an interface single crystal oxide layer that is amorphized to form a silicate layer which adsorbs the strain between the layers. Moreover, unlike past use of a SiC substrate, this embodiment of the invention is not limited by wafer size which is usually less than 50 mm in diameter for prior art SiC substrates.

The monolithic integration of nitride containing semiconductor compounds containing group III-V nitrides and silicon devices can be used for high temperature and high power RF applications and optoelectronics. GaN systems have particular use in the photonic industry for the blue/green and UV light sources and detection. High brightness light emitting diodes (LEDs) and lasers may also be formed within the GaN system.

FIGS. 21-23 schematically illustrate, in cross-section, the formation of another embodiment of a device structure in accordance with the invention. This embodiment includes a compliant layer that functions as a transition layer that uses clathrate or Zintl type bonding. More specifically, this embodiment utilizes an intermetallic template layer to reduce the surface energy of the interface between material layers thereby allowing for two dimensional layer by layer growth.

The structure illustrated in FIG. 21 includes a monocrystalline substrate 102, an amorphous interface layer 108 and an accommodating buffer layer 104. Amorphous interface layer 108 is formed on substrate 102 at the interface between substrate 102 and accommodating buffer layer 104 as previously described with reference to FIGS. 1 and 2. Amorphous interface layer 108 may comprise any of those materials previously described with reference to amorphous interface layer 28 in FIGS. 1 and 2. Substrate 102 is preferably silicon but may also comprise any of those materials previously described with reference to substrate 22 in FIGS. 1-3.

A template layer 130 is deposited over accommodating buffer layer 104 as illustrated in FIG. 22 and preferably comprises a thin layer of Zintl type phase material composed of metals and metalloids having a great deal of ionic character. As in previously described embodiments, template layer 130 is deposited by way of MBE, CVD, MOCVD, MEE, ALE, PVD, CSD, PLD, or the like to achieve a thickness of one monolayer. Template layer 130 functions as a “soft” layer with non-directional bonding but high crystallinity which absorbs stress build up between layers having lattice mismatch. Materials for template 130 may include, but are not limited to, materials containing Si, Bi, H, Ga, In, and Sb and, for example, SrAl₂, (MgCaYb)Ga₂, (Ca,Sr,Eu,Yb)In₂, BaGe₂As, and SrSn₂As₂

A monocrystalline material layer 126 is epitaxially grown over template layer 130 to achieve the final structure illustrated in FIG. 23. As a specific example, an SrAl₂ layer may be used as template layer 130 and an appropriate monocrystalline material layer 126 such as a compound semiconductor material GaAs is grown over the SrAl₂. The Al−Ti (from the accommodating buffer layer of layer of Sr_{z}Ba_{1-z}TiO₃ where z ranges from 0 to 1) bond is mostly metallic while the Al—As (from the GaAs layer) bond is weakly covalent. The Sr participates in two distinct types of bonding with part of its electric charge going to the oxygen atoms in the lower accommodating buffer layer 104 comprising Sr_{z}Ba_{1-z}TiO₃ to participate in ionic bonding and the other part of its valence charge being donated to Al in a way that is typically carried out with Zintl phase materials. The amount of the charge transfer depends on the relative electronegativity of elements comprising the template layer 130 as well as on the interatomic distance. In this example, Al assumes an sp3 hybridization and can readily form bonds with monocrystalline material layer 126, which in this example, comprises compound semiconductor material GaAs.

The compliant substrate produced by use of the Zintl type template layer used in this embodiment can absorb a large strain without a significant energy cost. In the above example, the bond strength of the Al is adjusted by changing the volume of the SrAl₂ layer thereby making the device tunable for specific applications which include the monolithic integration of III-V and Si devices and the monolithic integration of high-k dielectric materials for CMOS technology.

Clearly, those embodiments specifically describing structures having compound semiconductor portions and Group IV semiconductor portions, are meant to illustrate embodiments of the present invention and not limit the present invention. There are a multiplicity of other combinations and other embodiments of the present invention. For example, the present invention includes structures and methods for fabricating material layers which form semiconductor structures, devices and integrated circuits including other layers such as metal and non-metal layers. More specifically, the invention includes structures and methods for forming a compliant substrate which is used in the fabrication of semiconductor structures, devices and integrated circuits and the material layers suitable for fabricating those structures, devices, and integrated circuits. By using embodiments of the present invention, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters.

By the use of this type of substrate, a relatively inexpensive “handle” wafer overcomes the fragile nature of compound semiconductor or other monocrystalline material wafers by placing them over a relatively more durable and easy to fabricate base material. Therefore, an integrated circuit can be formed such that all electrical components, and particularly all active electronic devices, can be formed within or using the monocrystalline material layer even though the substrate itself may include a monocrystalline semiconductor material. Fabrication costs for compound semiconductor devices and other devices employing non-silicon monocrystalline materials should decrease because larger substrates can be processed more economically and more readily compared to the relatively smaller and more fragile substrates (e.g. conventional compound semiconductor wafers).

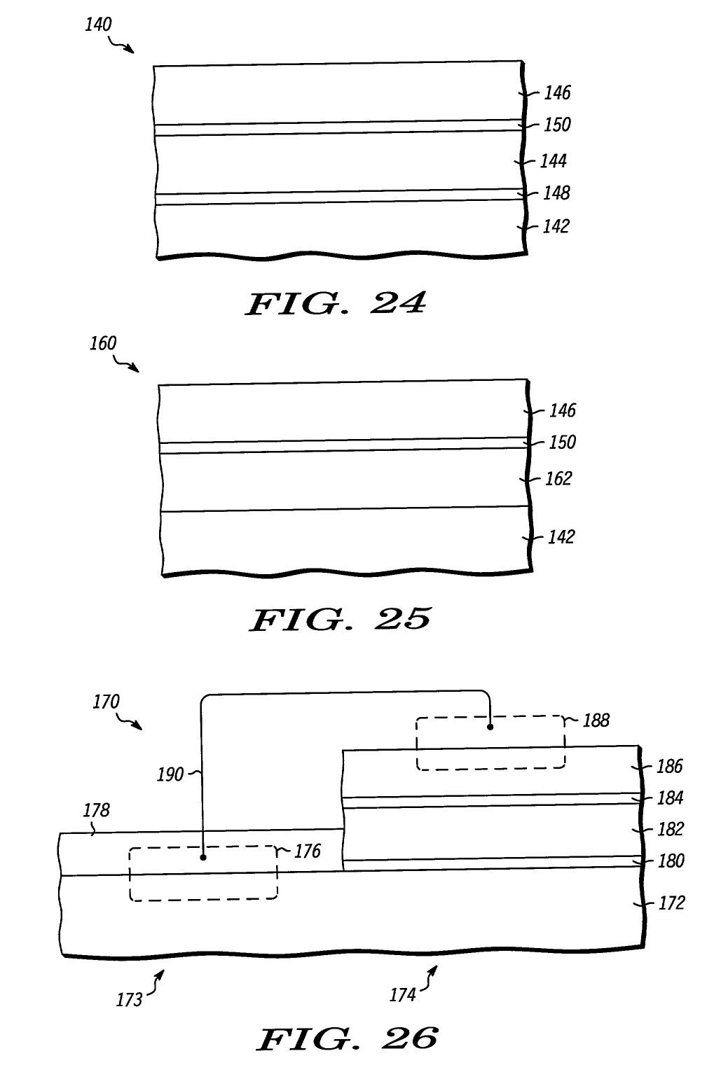

A portion of a semiconductor structure 140 formed in accordance with another embodiment of the invention is illustrated in FIG. 24. Like the previously described embodiments referred to in FIGS. 1-3, this embodiment of the invention involves the process of forming a compliant substrate for the epitaxial growth of single crystal materials.

Semiconductor structure 140 includes a monocrystalline substrate 142, a monocrystalline accommodating buffer layer 144, and a monocrystalline compound semiconductor material layer 146. Monocrystalline substrate 142, in accordance with an embodiment of the invention, may be formed of a material from Group IV of the periodic table. Examples of Group IV materials of the periodic table suitable for forming substrate 142 include silicon, germanium, mixed silicon and germanium, mixed silicon and carbon, mixed silicon, germanium and carbon, and the like. Preferably, substrate 142 is a wafer containing silicon or germanium and most preferably is a high quality monocrystalline silicon wafer as used in the semiconductor industry.

In accordance with one embodiment of the invention, structure 140 may also include a template layer 150 between the monocrystalline accommodating buffer layer 144 and the monocrystalline compound semiconductor material layer 146. Template layer 150 may be formed of any of the materials that comprise template layer 30 of FIGS. 1-3, template layer 60 of FIG. 12, capping layer 82 of FIG. 20, and template layer 130 of FIG. 23.

Accommodating buffer layer 144 is preferably formed of a monocrystalline oxide material epitaxially grown overlying substrate 142. Materials that are suitable for forming monocrystalline accommodating buffer layer 144 include any of those materials that comprise accommodating buffer layer 24 of FIGS. 1 and 2. In accordance with another embodiment of the invention, as the monocrystalline oxide material is formed overlying substrate 142, it is exposed to niobium so that accommodating buffer layer 144 terminates in a material having a lattice constant that is substantially matched to the lattice constant of monocrystalline compound semiconductor material layer 146. In one embodiment of the invention, the niobium is added to the monocrystalline oxide so that the accommodating buffer layer 144 has a constant concentration of niobium throughout the layer. Preferably, however, the niobium concentration in the accommodating buffer layer increases from a minimum value proximate to substrate 142 to a maximum value proximate to the monocrystalline compound semiconductor material layer 146. In this manner, accommodating buffer layer 144 has a first lattice constant proximate to the substrate 142 that is substantially matched to the lattice constant of the substrate and has a second lattice constant proximate to the monocrystalline compound semiconductor material layer 146 that is substantially matched to the lattice constant of layer 146. In an exemplary embodiment of the invention, accommodating buffer layer 144 may have a thickness in the range of from about 2 nm to about 100 nm and preferably has a thickness of about 5 nm.

In accordance with another embodiment of the invention, structure 140 also includes an amorphous interface layer 148 positioned between the monocrystalline substrate 142 and the monocrystalline accommodating buffer layer 144. Amorphous interface layer 148 is preferably an oxide formed by the oxidation of the surface of substrate 142, which may occur during growth of accommodating buffer layer 144. The thickness of layer 148 is sufficient to relieve strain attributed to mismatches between the lattice constants of substrate 142 and accommodating buffer layer 144. Typically, layer 148 has a thickness in the range of approximately 0.5-5 nm, and, preferably has a thickness in the range of approximately 1-2 nm. In accordance with one embodiment of the invention, when monocrystalline substrate 142 is formed of silicon, amorphous interface layer 148 is formed of silicon oxide.

The material for monocrystalline material layer 146 can be selected, as desired, for a particular structure or application and may be formed of any of those materials that comprise monocrystalline material layer 26 of FIGS. 1-3. Examples include GaAs, GaInAs, InP, CdS, CdHgTe, ZnSe, ZnSSe, and the like. However, monocrystalline material layer 146 may also comprise other semiconductor materials, metals, or non-metal materials which are used in the formation of semiconductor structures, devices and/or integrated circuits.

In accordance with one exemplary embodiment of the invention, monocrystalline substrate 142 is a silicon substrate oriented in the (100) direction and monocrystalline compound semiconductor material layer 146 is a material layer formed of GaAs. In accordance with this embodiment of the invention, accommodating buffer layer 144 is a monocrystalline layer of SrTi₁₋ₓNbₓO₃, where x increases from 0 proximate to substrate 142 to 0.56 proximate to the monocrystalline compound semiconductor material layer 146. Accommodating buffer layer 144 has a (100) crystalline orientation rotated by 45° with respect to the underlying substrate 142. With this composition and orientation, accommodating buffer layer 144 has a lattice constant proximate to substrate 142 that is substantially matched to the lattice constant of silicon substrate 142 and has a lattice constant proximate to monocrystalline compound semiconductor material layer 146 that is substantially matched to the lattice constant of the GaAs layer 146. Accommodating buffer layer 144 can have a thickness of about 2 to about 100 nm and preferably has a thickness of about 5 nm. The amorphous interface layer is a layer of silicon oxide (SiOₓ) formed at the interface between the silicon substrate and the accommodating buffer layer. The amorphous interface layer of silicon oxide can have a thickness of about 0.5 to about 5 nm, and preferably a thickness of about 1 to 2 nm. To facilitate the epitaxial growth of the GaAs layer on the monocrystalline oxide, a template layer is formed by capping the accommodating buffer layer. The template layer 150 is preferably 1-10 monolayers of Ti—As, Sr—O—As, Sr—Ga—O, or Sr—Al—O. By way of a preferred example, 1-2 monolayers of Ti—As or Sr—Ga—O have been illustrated to successfully grow GaAs layers.

In accordance with another exemplary embodiment of the invention, monocrystalline substrate 142 is a silicon substrate as described above. The accommodating buffer layer is a monocrystalline layer of BaTi₁₋ₓNbₓO₃, where x ranges from 0 to 1. The value of x can be selected so that the lattice constant of the accommodating buffer layer is substantially matched to the lattice constant of the overlying monocrystalline compound semiconductor material layer 146. An amorphous interface layer of silicon oxide may be formed at the interface between the silicon substrate and the accommodating buffer layer. The concentration of niobium in accommodating buffer layer 144 may be constant throughout the layer and the lattice structure of layer 144 exhibits a 45° rotation with respect to the silicon substrate lattice structure. Alternatively, the concentration of niobium may increase from proximate to the substrate 142 to proximate to the monocystalline compound semiconductor material layer. The accommodating buffer layer 144 can have a thickness of about 2-100 nm and preferably has a thickness of at least 5 nm to ensure adequate crystalline and surface quality. Monocrystalline compound semiconductor material layer 146 may be a compound semiconductor layer of AlGaAs having a thickness that generally depends on the application for which the layer is being prepared. A suitable template layer 150 for this structure is 1-10 monolayers of Ti—As, Ba—O—As or Ba—Ga—O.

FIG. 25 schematically illustrates, in cross section, a portion of a semiconductor structure 160 in accordance with a further embodiment of the invention. Structure 160 is similar to structure 140, except that structure 160 includes an amorphous layer 162, rather than monocrystalline accommodating buffer layer 144 and amorphous interface layer 148.

Amorphous layer 162 may be formed by a process similar to that previously described for the formation of amorphous layer 36 of FIG. 3. Amorphous layer 162 may be formed by first forming a monocrystalline accommodating buffer layer 144 and an amorphous interface layer 148 in a similar manner to that described above with reference to semiconductor structure 140 of FIG. 24. Monocrystalline compound semiconductor material layer 146 may then be epitaxially grown overlying the accommodating buffer layer. Monocrystalline compound semiconductor material layer 146 may be grown to its desired thickness or, alternatively, a seed layer of the monocrystalline compound semiconductor material layer may be grown. Semiconductor structure 160 is then exposed to an anneal process to convert at least a portion of the monocrystalline accommodating buffer layer to an amorphous layer. Amorphous layer 162 formed in this manner comprises materials from the monocrystalline accommodating buffer layer and the amorphous interface layer. Thus, layer 162 may comprise one or two amorphous layers. Formation of amorphous layer 162 between substrate 142 and monocrystalline compound semiconductor material layer 146 relieves stresses between layers 142 and 146 and provides a compliant substrate for subsequent processing—e.g., further growth of layer 146.

The following example illustrates a process, in accordance with one embodiment of the invention, for fabricating structure 140. The process previously described for the removal of any native oxide on the surface of silicon substrate 22 and the preparation of silicon substrate 22 for growth of a monocrystalline oxide layer with reference to FIGS. 1-3 may be used to prepare silicon substrate 142. Following preparation of the silicon substrate 142, the resultant surface of substrate 142 may exhibit an ordered 2×1 structure that includes strontium, oxygen, and silicon. The ordered 2×1 structure forms a template for the ordered growth of an overlying layer of a monocrystalline oxide. The substrate is then cooled to a temperature in the range of about 200-800° C., preferably 350-450°, and an accommodating buffer layer formed initially of strontium titanate is grown on the template layer by MBE. The MBE process is initiated by opening shutters in the MBE apparatus to expose strontium, titanium and oxygen sources. The ratio of strontium and titanium is approximately 1:1. The partial pressure of oxygen is initially set at a minimum value to grow stoichiometric strontium titanate at a growth rate of about 0.1-0.8 nm per minute, preferably 0.3-0.5 nm per minute. After initiating growth of the strontium titanate, a shutter(s) in the MBE apparatus is opened to expose a niobium source. The concentration of the niobium is increased during the reaction so that the accommodating buffer layer is grown with a composition of SrT₁₋ₓNbₓO₃, with x increasing from 0 to approximately 0.56. The accommodating buffer layer is grown to its desired thickness and terminates with a composition having approximately a 1:1 ratio of titanium and niobium. Preferably, the accommodating buffer layer terminates in a composition comprising SrTi_{0.44}Nb_{0.56}O₃. After initiating growth of the accommodating buffer layer, the partial pressure of oxygen is increased above the initial minimum value. The overpressure of oxygen causes the growth of an amorphous silicon oxide layer at the interface between the underlying substrate and the accommodating buffer layer. The growth of the silicon oxide layer results from the diffusion of oxygen through the strontium titanate niobate layer to the interface where the oxygen reacts with silicon at the surface of the underlying substrate. The strontium titanate niobate layer grows as an ordered (100) monocrystal with the (100) crystalline orientation rotated by 45° with respect to the underlying substrate. Strain that otherwise might exist in the strontium titanate niobate layer because of the small mismatch in lattice constant between the silicon substrate and the growing crystal is relieved in the amorphous silicon oxide interface layer.

After the strontium titanate niobate layer has been grown to the desired thickness, the monocrystalline strontium titanate niobate layer is capped by a template layer that is conducive to the subsequent growth of an epitaxial layer of a desired monocrystalline material. For example, for the subsequent growth of a monocrystalline compound semiconductor material layer of GaAs, the MBE growth of the strontium titanate niobate monocrystalline layer can be capped by terminating the growth with 0.5-2 monolayers of titanium, 0.5-2 monolayers of titanium-oxygen, 0.5-2 monolayers of strontium, or with 0.5-2 monolayers of strontium-oxygen. Following the formation of this capping layer, arsenic is deposited to form a Ti—As bond, a Ti—O—As bond, a Si—As bond or a Sr—O—As bond. Following the formation of the template, gallium is subsequently introduced to react with the arsenic and gallium arsenide forms. Alternatively, gallium can be deposited on the capping layer and arsenic is subsequently introduced with the gallium to form the GaAs.

Structure 160, illustrated in FIG. 25, may be formed by growing an accommodating buffer layer 144, as described above, and forming an amorphous interface layer 148 between the substrate 142 and the accommodating buffer layer 144. The monocrystalline compound semiconductor material layer 146 may then be grown, as described above, to its desired thickness or, alternatively, a seed layer may be grown. The accommodating buffer layer 144 and the amorphous interface layer 148 are then exposed to an anneal process sufficient to change at least a portion the crystalline structure of the accommodating buffer layer from monocrystalline to amorphous, thereby forming an amorphous layer such that the combination of the amorphous oxide layer and the now amorphous accommodating buffer layer form a single amorphous oxide layer 162. The anneal process may include a rapid thermal process with a peak temperature of about 700° C. to about 1000° C. and a process time of about 5 seconds to about 20 minutes. However, other suitable anneal processes may be employed to convert the accommodating buffer layer to an amorphous layer in accordance with the present invention. For example, electron beam annealing or “conventional” thermal annealing processes may be used to form layer 162. After annealing, growth of monocrystalline compound semiconductor material layer 146 may be continued.

The process described above illustrates a process for forming a semiconductor structure including a silicon substrate, an overlying niobate-containing accommodating buffer layer, and a monocrystalline compound semiconductor material layer by the process of MBE. The process can also be carried out by the process of CVD, MOCVD, MEE, ALE, PVD, CSD, PLD, or the like.

FIG. 27 illustrates schematically, in cross section, a device structure 170 in accordance with a further embodiment. Device structure 170 includes a monocrystalline semiconductor substrate 172, preferably a monocrystalline silicon wafer. Monocrystalline semiconductor substrate 172 includes two regions, 173 and 174. An electrical semiconductor component generally indicated by the dashed line 176 is formed, at least partially, in region 173. Electrical component 176 can be a resistor, a capacitor, an active semiconductor component such as a diode or a transistor or an integrated circuit such as a CMOS integrated circuit. For example, electrical semiconductor component 176 can be a CMOS integrated circuit configured to perform digital signal processing or another function for which silicon integrated circuits are well suited. The electrical semiconductor component in region 173 can be formed by conventional semiconductor processing as is well known and widely practiced in the semiconductor industry. A layer of insulating material 178 such as a layer of silicon dioxide or the like may overlie electrical semiconductor component 176.

Insulating material 178 and any other layers that may have been formed or deposited during the processing of semiconductor component 176 in region 173 are removed from the surface of region 174 to provide a bare silicon surface in that region. As is well known, bare silicon surfaces are highly reactive and a native silicon oxide layer can quickly form on the bare surface. A layer (preferable 1-3 monolayers) of strontium or strontium and oxygen is deposited onto the native oxide layer on the surface of region 174 and is reacted with the oxidized surface to form a first template layer (not shown).

In accordance with one embodiment, a monocrystalline accommodating buffer layer 182 with a graded concentration of niobium therethrough is formed overlying the template layer by a process of MBE. Reactants including strontium, titanium and oxygen may be deposited onto the template layer to form the accommodating buffer layer. Alternatively, barium may be substituted for the strontium. As the accommodating buffer layer is deposited onto the template layer, niobium is introduced to the reaction so that the accommodating buffer layer has the composition of SrTi₁₋ₓNbₓO₃, with x increasing from 0 to approximately 0.56 as the accommodating buffer layer is deposited onto the template. The accommodating buffer layer preferably terminates with a composition of SrTi_{0.44}Nb_{0.56}O₃. Initially during the deposition of the accommodating buffer layer, the partial pressure of oxygen is kept near the minimum necessary to fully react with the strontium and titanium to form a monocrystalline strontium titanate niobate layer. The partial pressure of oxygen is then increased to provide an overpressure of oxygen and to allow oxygen to diffuse through the growing monocrystalline accommodating buffer layer. The oxygen diffusing through the strontium titanate niobate reacts with the silicon substrate 172 to form an amorphous layer 180 of silicon oxide at the interface between silicon substrate 172 and accommodating buffer layer 182. As described above, layers 180 and 182 may be subject to an annealing to form a single amorphous accommodating layer.

In accordance with an embodiment of the present invention, the step of depositing the monocrystalline accommodating buffer layer 182 is terminated by depositing a second template layer 184, which can be 0.5-10 monolayers of titanium, strontium (or barium), strontium and oxygen (or barium and oxygen), or titanium and oxygen. A layer 186 of a monocrystalline compound semiconductor material is then deposited overlying the second template layer 184 by MBE. The deposition of layer 186 is initiated by depositing a layer of arsenic onto template 184. This initial step is followed by depositing gallium and arsenic to form monocrystalline gallium arsenide.

In accordance with a further embodiment, a semiconductor component, generally indicated by a dashed line 188 is formed in compound semiconductor layer 186. Semiconductor component 188 can be any active or passive component, and preferably is a semiconductor laser, light emitting diode, photodetector, heterojunction bipolar transistor (HBT), high frequency MESFET, or other component that utilizes and takes advantage of the physical properties of compound semiconductor materials. A metallic conductor schematically indicated by the line 190 can be formed to electrically couple device 188 and device 176, thus implementing an integrated device that includes at least one component formed in silicon substrate 172 and one device formed in monocrystalline compound semiconductor material layer 186. Although illustrative structure 170 has been described as a structure formed on a silicon substrate 172 and having a strontium (or barium) titanate niobate layer 182 and a gallium arsenide layer 186, similar devices can be fabricated using other substrates, monocrystalline accommodating buffer layers and other compound semiconductor layers as described elsewhere in this disclosure.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

We claim:

1. A semiconductor structure comprising:
a monocrystalline substrate;
a monocrystalline accommodating buffer layer overlying said monocrystalline substrate, wherein said monocrystalline accommodating buffer layer is formed of a monocrystalline oxide that is exposed to a concentration of niobium while being deposited overlying said monocrystalline substrate; and
a monocrystalline compound semiconductor material layer overlying said monocrystalline accommodating buffer layer.

2. The semiconductor structure of claim 1, wherein said concentration of niobium is kept constant while said monocrystalline oxide is deposited overlying said monocrystalline substrate.

3. The semiconductor structure of claim 1, wherein said concentration of niobium is increased as said monocrystalline oxide is deposited overlying said monocrystalline substrate.

4. The semiconductor structure of claim 1, said monocrystalline compound semiconductor material layer comprising a material selected from one of: Group III-V compound semiconductors, mixed III-V compound semiconductors, Group II-VI compound semiconductors, mixed II-VI compound semiconductors, Group IV-VI compounds semiconductors, and mixed IV-VI compound semiconductors.

5. The semiconductor structure of claim 1, wherein said monocrystalline compound semiconductor material layer comprises a material selected from at least one of: gallium arsenide, gallium aluminum arsenide, gallium indium arsenide, indium phosphide, cadmium sulfide, cadmium mercury telluride, zinc selenide, zinc sulfur selenide, lead selenide, lead telluride, and lead sulfide selenide.

6. The semiconductor structure of claim 1, wherein said monocrystalline oxide comprises a material selected from at least one of: alkaline earth metal titanates, alkaline earth metal zirconates, alkaline earth metal hafnates, alkaline earth metal tantalates, alkaline earth metal ruthenates, alkaline earth metal vanadates, perovskite oxides such as alkaline earth metal tin-based perovskites, lanthanum aluminate, lanthanum scandium oxide, and gadolinium oxide.

7. The semiconductor structure of claim 1, further comprising a template layer formed overlying said accommodating buffer layer and underlying said monocrystalline compound semiconductor material layer.

8. The semiconductor structure of claim 7, wherein said template layer comprises a Zintl-type phase material.

9. The semiconductor structure of claim 7, wherein said template layer comprises a surfactant material.

10. The semiconductor structure of claim 9, wherein said template layer further comprises a capping layer.

11. The semiconductor structure of claim 10, wherein said capping layer is formed by exposing said surfactant material to a cap-inducing material.

12. The semiconductor structure of claim 7, wherein said template layer comprises a capping layer formed of about 1-10 monolayers of one of a material M—N and a material M—O—N, wherein M is selected from at least one of Zr, Hf, Sr, Ti, and Ba and N is selected from at least one of As, P, Ga, Al, and In.

13. The semiconductor structure of claim 1, wherein said monocrystalline accommodating buffer layer is formed of a monocrystalline material and is subsequently heat treated to convert at least a portion of said monocrystalline material to an amorphous material.

14. The semiconductor structure of claim 1, further comprising an amorphous interface layer overlying said monocrystalline substrate and underlying said monocrystalline accommodating buffer layer.

15. The semiconductor structure of claim 1, said monocrystalline substrate comprising silicon.

16. The semiconductor structure of claim 2, wherein said accommodating buffer layer comprises SrTi_{0.44}Nb_{0.56}O₃.

17. The semiconductor structure of claim 3, wherein said accommodating buffer layer comprises SrTi₁₋ₓNbₓO₃, where x increases from about zero to about 0.56 as said accommodating buffer layer is deposited overlying said monocrystalline substrate.

18. The semiconductor structure of claim 1, said accommodating buffer layer having thickness of from about 2 to about 100 nanometers.

19. A semiconductor structure comprising:
a monocrystalline substrate having a first lattice constant;
a monocrystalline accommodating buffer layer overlying said monocrystalline substrate, wherein upon proper orientation said monocrystalline accommodating buffer layer has a second lattice constant proximate to said monocrystalline substrate, said second lattice constant substantially matched to said first lattice constant; and
a monocrystalline compound semiconductor material layer overlying said monocrystalline accommodating buffer layer, said monocrystalline compound semiconductor material layer having a third lattice constant,
wherein said monocrystalline accommodating buffer layer is formed of a monocrystalline oxide which is exposed to a concentration of niobium while being deposited overlying said monocrystalline substrate such that said monocrystalline accommodating buffer layer has a fourth lattice constant proximate to said monocrystalline compound semiconductor material layer, said fourth lattice constant being substantially matched to said third lattice constant.

20. The semiconductor structure of claim 19, said monocrystalline compound semiconductor material layer comprising a material selected from one of: Group III-V compound semiconductors, mixed III-V compound semiconductors, Group II-VI compound semiconductors, mixed II-VI compound semiconductors, Group IV-VI compound semiconductors, and mixed IV-VI compound semiconductors.

21. The semiconductor structure of claim 19, wherein said monocrystalline compound semiconductor material layer comprises a material selected from at least one of: gallium arsenide, gallium aluminum arsenide, gallium indium arsenide, indium phosphide, cadmium sulfide, cadmium mercury telluride, zinc selenide, zinc sulfur selenide, lead selenide, lead telluride, and lead sulfide selenide.

22. The semiconductor structure of claim 19, wherein said monocrystalline accommodating buffer layer comprises a material selected from at least one of: alkaline earth metal titanates, alkaline earth metal zirconates, alkaline earth metal hafnates, alkaline earth metal tantalates, alkaline earth metal ruthenates, alkaline earth metal vanadates, perovskite oxides such as alkaline earth metal tin-based perovskites, lanthanum aluminate, lanthanum scandium oxide, and gadolinium oxide.

23. The semiconductor structure of claim 19, wherein said monocrystalline substrate comprises silicon.

24. The semiconductor structure of claim 23, wherein said monocrystalline compound semiconductor material layer comprises GaAs and said monocrystalline accommodating buffer layer comprises SrTi₁₋ₓNbₓO₃, where x increases from about zero proximate to said monocrystalline substrate to about 0.56 proximate to said monocrystalline compound semiconductor material layer.

25. The semiconductor structure of claim 19, further comprising a template layer formed overlying said accommodating buffer layer and underlying said monocrystalline compound semiconductor material layer.

26. The semiconductor structure of claim 25, wherein said template layer comprises a Zintl-type phase material.

27. The semiconductor structure of claim 25, wherein said template layer comprises a surfactant material.

28. The semiconductor structure of claim 27, wherein said template layer further comprises a capping layer.

29. The semiconductor structure of claim 28, wherein said capping layer is formed by exposing said surfactant material to a cap-inducing material.

30. The semiconductor structure of claim 25, wherein said template layer comprises a capping layer formed of about 1-10 monolayers of one of a material M—N and a material M—O—N, wherein M is selected from at least one of Zr, Hf, Sr, Ti, and Ba and N is selected from at least one of As, P, Ga, Al, and In.

31. The semiconductor structure of claim 19, wherein said monocrystalline accommodating buffer layer is formed of a monocrystalline material and is subsequently heat treated to convert at least a portion of said monocrystalline material to an amorphous material.

32. The semiconductor structure of claim 19, further comprising an amorphous interface layer overlying said monocrystalline substrate and underlying said monocrystalline accommodating buffer layer.

33. A process for fabricating a semiconductor structure, the process comprising:
providing a monocrystalline substrate;
forming a monocrystalline accommodating buffer layer overlying said monocrystalline substrate by depositing a monocrystalline oxide overlying said monocrystalline substrate while exposing said monocrystalline oxide to a concentration of niobium during at least a portion of said depositing, said monocrystalline accommodating buffer layer terminating in a material having a first lattice constant; and
epitaxially forming a monocrystalline compound semiconductor material layer overlying said monocrystalline accommodating buffer layer, said first lattice constant being substantially matched to a lattice constant of said monocrystalline compound semiconductor material layer.

34. The process of claim 33, wherein said monocrystalline oxide has a second lattice constant proximate to said monocrystalline substrate, said second lattice constant being substantially matched to a lattice constant of said monocrystalline substrate.

35. The process of claim 33, wherein said concentration of niobium is substantially constant during said exposing.

36. The process of claim 33, wherein said concentration of niobium is increased during said exposing.

37. The process of claim 33, said monocrystalline substrate comprising silicon.

38. The process of claim 33, wherein said accommodating buffer layer comprises SrTi_{0.44}Nb_{0.56}O₃.

39. The process of claim 33, wherein said accommodating buffer layer comprises SrTi₁₋ₓNbₓO₃, where x increases from about zero proximate to said monocrystalline substrate to about 0.56 proximate to said monocrystalline compound semiconductor material layer.

40. The process of claim 33, said accommodating buffer layer having thickness of from about 2 to about 100 nanometers.

41. The process of claim 33, said monocrystalline compound semiconductor material layer comprising a material selected from one of: Group III-V compound semiconductors, mixed III-V compound semiconductors, Group II-VI compound semiconductors, mixed II-VI compound semiconductors, Group IV-VI compounds semiconductors, and mixed IV-VI compound semiconductors.

42. The process of claim 33, wherein said monocrystalline compound semiconductor material layer comprises a material selected from at least one of: gallium arsenide, gallium aluminum arsenide, gallium indium arsenide, indium phosphide, cadmium sulfide, cadmium mercury telluride, zinc selenide, zinc sulfur selenide, lead selenide, lead telluride, and lead sulfide selenide.

43. The process of claim 33, wherein said monocrystalline oxide comprises a material selected from at least one of: alkaline earth metal titanates, alkaline earth metal zirconates, alkaline earth metal hafnates, alkaline earth metal tantalates, alkaline earth metal ruthenates, alkaline earth metal vanadates, perovskite oxides such as alkaline earth metal tin-based perovskites, lanthanum aluminate, lanthanum scandium oxide, and gadolinium oxide.

44. The process of claim 33, further comprising forming a template layer overlying said accommodating buffer layer and underlying said monocrystalline compound semiconductor material layer.

45. The process of claim 44, wherein said forming a template layer comprises capping said monocrystalline accommodating buffer layer with about 1-10 monolayers of a material M—N and a material M—O—N, wherein M is selected from at least one of Zr, Hf, Sr, Ti, and Ba and N is selected from at least one of As, P, Ga, Al, and In.

46. The process of claim 33, further comprising forming an amorphous interface layer between said monocrystalline substrate and said monocrystalline accommodating buffer layer.

47. A semiconductor device structure comprising:
a monocrystalline silicon substrate;
a monocrystalline accommodating buffer layer overlying said monocrystalline silicon substrate, wherein said monocrystalline accommodating buffer layer is formed of a monocrystalline oxide that is exposed to a concentration of niobium while being deposited overlying said monocrystalline substrate;
a monocrystalline compound semiconductor material layer overlying said monocrystalline accommodating buffer layer;
a first semiconductor component, at least a portion of which is formed in said monocrystalline silicon substrate; and
a second semiconductor component, at least a portion of which is formed in said monocrystalline compound semiconductor material layer, said second semiconductor component being electrically coupled to said first semiconductor component.

48. The semiconductor device structure of claim 47, wherein said concentration of niobium is kept constant while said monocrystalline oxide is deposited overlying said monocrystalline substrate.

49. The semiconductor device structure of claim 47, wherein said concentration of niobium is increased as said monocrystalline oxide is deposited overlying said monocrystalline substrate.

50. The semiconductor structure of claim 47, wherein said monocrystalline oxide comprises a material selected from at least one of: alkaline earth metal titanates, alkaline earth metal zirconates, alkaline earth metal hafnates, alkaline earth metal tantalates, alkaline earth metal ruthenates, alkaline earth metal vanadates, perovskite oxides such as alkaline earth metal tin-based perovskites, lanthanum aluminate, lanthanum scandium oxide, and gadolinium oxide.

51. The semiconductor device structure of claim 47, further comprising a template layer formed overlying said accommodating buffer layer and underlying said monocrystalline compound semiconductor material layer.

52. The semiconductor device structure of claim 47, wherein said monocrystalline accommodating buffer layer is formed of a monocrystalline material and is subsequently heat treated to convert at least a portion of said monocrystalline material to an amorphous material.

53. The semiconductor device structure of claim 47, further comprising an amorphous interface layer overlying said monocrystalline substrate and underlying said monocrystalline accommodating buffer layer.

54. The semiconductor device structure of claim 47, said monocrystalline substrate comprising silicon.

55. The semiconductor device structure of claim 48, wherein said accommodating buffer layer comprises SrTi_{0.44}Nb_{0.56}O₃.

56. The semiconductor device structure of claim 49, wherein said accommodating buffer layer comprises SrTi₁₋ₓNbₓO₃, where x increases from about zero proximate to said monocrystalline silicon substrate to about 0.56 proximate to said monocrystalline compound semiconductor material layer.

57. The semiconductor device structure of claim 1, said accommodating buffer layer having thickness of from about 2 to about 100 nanometers.
